(19) United States
(12) Patent Application Publication
(10) Pub. No.: US 2023/0250532 A1
(43) Pub. Date: Aug. 10, 2023

(54) REACTOR COOLING SYSTEM

(71) Applicant: ASM IP Holding B.V., Almere (NL)

(72) Inventors: Rohan Vijay Rane, Tempe, AZ (US); Jianqiu Huang, Phoenix, AZ (US); Jason Burgad, Mesa, AZ (US); Yingzong Bu, Powell, OH (US)

(21) Appl. No.: 18/105,275

(22) Filed: Feb. 3, 2023

Related U.S. Application Data
(60) Provisional application No. 63/307,860, filed on Feb. 8, 2022.

(51) Int. Cl. C23C 16/46; F28F 1/12; C23C 16/455

(52) U.S. Cl. CPC C23C 16/463; F28F 1/12; C23C 16/45565; F28F 2275/04

(57) ABSTRACT

Cooling systems for the cooling of various sections of a gas phase reactor system, including a gas distribution sections and lower chamber sections, are disclosed. Exemplary cooling systems include cooling plates to regulate the temperature of the gas phase reactor system.

### CROSS-REFERENCE TO RELATED APPLICATIONS

This application is a nonprovisional of, and claims priority to and the benefit of, U.S. Provisional Patent Application No. 63/307,860, filed Feb. 8, 2022 and entitled “REACTOR COOLING SYSTEM,” which is hereby incorporated by reference herein.

### FIELD OF INVENTION

The present disclosure generally relates to gas-phase reactor systems. More particularly, the disclosure relates to cooling systems suitable for use with gas-phase reactor systems.

### BACKGROUND OF THE DISCLOSURE

Gas-phase reactors, such as chemical vapor deposition (CVD) reactors and the like, can be used for a variety of applications, including depositing and etching materials on a substrate surface, and cleaning of a surface of the substrate. For example, gas-phase reactors can be used to deposit layers on a substrate to form devices, such as semiconductor devices, flat panel display devices, photovoltaic devices, microelectromechanical systems (MEMS), and the like.

During the manufacture of devices, it is often desirable to heat a substrate to facilitate a surface reaction thereon and to cool a portion of the gas phase reactor system to obtain desired deposition and/or etch rates, while mitigating non-uniformity of the deposited and/or etched material on the substrate surface. Cooling a portion of the reactor system may also mitigate undesired reactions with surfaces of or within the reaction chamber.

Some cooling systems utilize cooling plates to cool a portion of the gas phase reactor system. Such cooling systems can be susceptible to galvanic and pitting corrosion of a cooling plate, which can lead to increased non-uniformity of cooling of the portion of the gas phase reactor system, which, in turn, can lead to increased non-uniformity of deposition, etch, or cleaning processes within the gas-phase reactor system. Further, because of the deficiencies with typical cooling systems, a duty cycle of a typical cooling system may be relatively low and/or vary between reaction chambers—e.g., reaction chambers within the same reactor system. It is generally desirable to use a cooling system that can mitigate thermal non-uniformity during operation. Additionally or alternatively, it is desirable to have relatively high duty cycles of the cooling systems. Further, it is generally desirable to have consistency between cooling systems.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

In accordance with various embodiments of the disclosure, cooling systems for a gas phase reactor are provided. An exemplary cooling system can include a first plate comprising a first surface, a first width and a first thickness, and a second plate comprising a second surface, a second width and a second thickness. A groove can be formed within the first plate and extend to the first surface of the first plate. The first plate and the second plate can be coupled together at the first surface and the second surface to form a conduit comprising the groove enclosed by a portion of the second surface. In accordance with examples of embodiments, a metal tube can be disposed within the conduit; the metal tube can comprise a cooling fluid inlet at a first end of the metal tube and a cooling fluid outlet at a second end of the metal tube.

In accordance with examples of embodiments, the first plate and the second plate can comprise or be formed of aluminum. Additionally, the first plate and the second plate can be brazed together at the first surface and the second surface. In accordance with examples of embodiments, the metal tube can comprise or be formed of stainless steel.

In accordance with examples of embodiments, the first plate and the second plate each can form a partial annular structure. The second plate can comprise an inner diameter and an outer diameter. The groove can comprise an arcuate shape comprising a groove diameter that is greater than the inner diameter and less than the outer diameter.

In accordance with examples of embodiments, the first plate and the second plate can each form an annular structure, where the first plate comprises an inner diameter and an outer diameter. The groove can be continuous and can comprise a plurality of concentric arcuate shaped sections.

In accordance with additional embodiments of the disclosure, another exemplary cooling system is provided. The cooling system can include a first plate and a second plate, wherein the first plate and the second plate can be coupled using one or more of a weld and a brazing material. The first plate can comprise a first surface, a first thickness and a first width. A groove can be formed within the first plate. The groove can extend to the first surface of the first plate. The second plate can comprise a first layer and a second layer. The second plate can comprise a second thickness and a second width. The first plate and the second plate can be coupled using the one or more of a weld and the brazing material at the first surface and the first layer. The first layer and the first surface can form a conduit comprising the groove enclosed by a portion of the first layer. The cooling system can also comprise a cooling fluid inlet and a cooling fluid outlet. The cooling fluid inlet and the cooling fluid outlet are fluidly connected to the conduit.

In accordance with examples of embodiments, the second layer can be formed of a second metal. The first layer can comprise or be formed of stainless steel. The first plate can comprise or be formed of stainless steel. The weld can be directly in contact with the first layer of the second plate and the first surface of the first plate.

In accordance with examples of embodiments, the cooling system can comprise a metal tube. The metal tube can be disposed within the conduit. Additionally, the groove can comprise a serpentine path between the cooling fluid inlet and the cooling fluid outlet. The groove can also comprise a continuous serpentine path between the cooling fluid inlet and the cooling fluid outlet.

Exemplary cooling systems can further comprise a coupling assembly for connecting a cooling fluid inlet and a cooling fluid outlet to a cooling fluid source.

In accordance with additional embodiments of the disclosure, a gas phase reactor including a cooling system is provided. The gas phase reactor can comprise a reaction chamber comprising an upper region and a lower region. A showerhead can be disposed within the upper region. A first cooling system can be disposed below the lower region. The first cooling system can be a cooling system described herein. Additionally or alternatively, the gas-phase reactor includes a second cooling system, such as a cooling system described herein. The second cooling system can be disposed above the showerhead. Exemplary gas-phase reactor systems can include one or more cooling systems.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1A illustrates a perspective view of a cooling system in accordance with exemplary embodiments of the disclosure.

FIG. 1B illustrates a top view of a cooling system in accordance with exemplary embodiments of the disclosure.

FIG. 2 illustrates a first plate of the cooling system in accordance with exemplary embodiments of the disclosure.

FIG. 3A illustrates another cooling system in accordance with exemplary embodiments of the disclosure.

FIG. 3B illustrates a top view of a cooling system in accordance with exemplary embodiments of the disclosure.

FIG. 4 illustrates a top view of a first plate of a cooling system in accordance with exemplary embodiments of the disclosure.

FIG. 5 illustrates a cross-sectional view of a cooling system in accordance with exemplary embodiments of the disclosure.

FIG. 6 illustrates a cross-sectional view of a cooling system in accordance with exemplary embodiments of the disclosure.

FIG. 7A illustrates a perspective cross-sectional view of a portion of one chamber of a gas phase reactor suitable for use with a cooling system in accordance with exemplary embodiments of the disclosure.

FIG. 7B illustrates a perspective view of the gas phase reactor in accordance with exemplary embodiments of the disclosure.

FIG. 7C illustrates a top view of the gas phase reactor with an annular cooling system in accordance with exemplary embodiments of the disclosure.

FIG. 7D illustrates a bottom view of the gas phase reactor with a partial annular cooling system in accordance with exemplary embodiments of the disclosure.

It will be appreciated that elements in the figures are illustrated for simplicity and clarity and have not necessarily been drawn to scale. For example, the dimensions of some of the elements in the figures can be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to cooling systems for cooling a portion of gas phase reactor system using one or more cooling plates. By way of examples, the cooling systems can include a bi-metal cooling system or a brazed cooling system. Exemplary cooling systems can be used to cool various parts or portions of a gas-phase reactor system, such as a gas distribution device (e.g., a showerhead) and/or a lower chamber of a reactor. Exemplary gas-phase reactor systems can include various combinations of the cooling systems.

Exemplary cooling systems can comprise a first plate and a second plate. In accordance with examples of these embodiments, the first plate can comprise a groove and the second plate can comprise a second surface coupled to a first surface of the first plate, such that the second surface and the groove can form a conduit. The conduit can be used as a cooling channel to circulate a coolant to the cooling system. In accordance with examples of the disclosure, a metal tube can be disposed within the conduit.

In this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

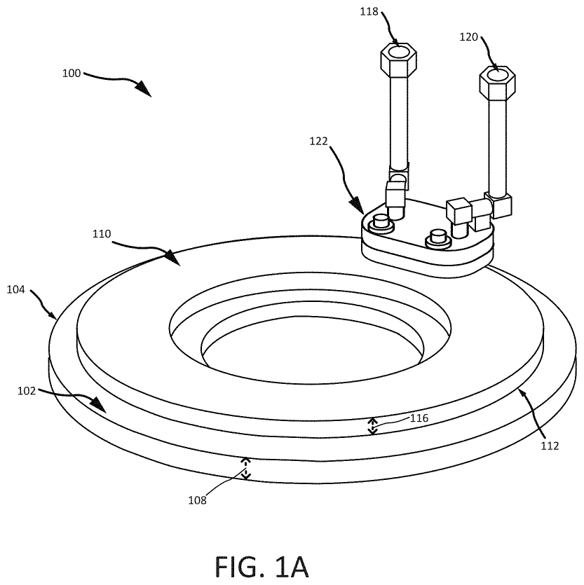

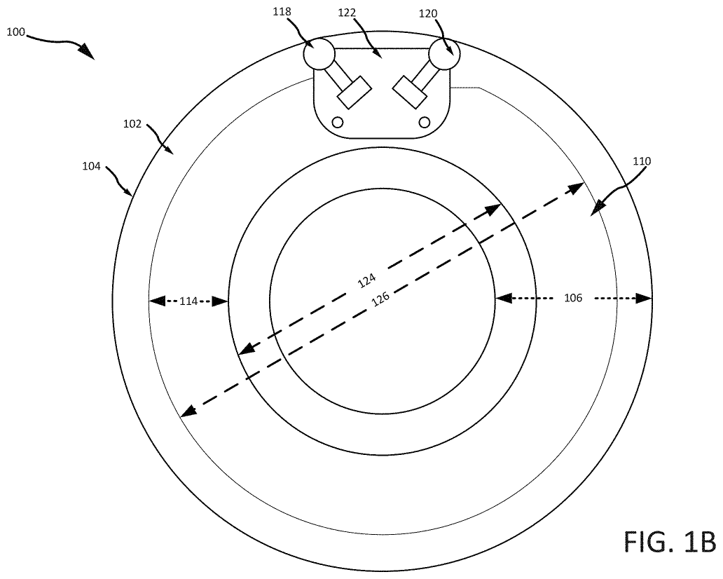

Turning now to the figures, FIGS. 1A and 1B illustrate an exemplary cooling system 100 in accordance with examples of the disclosure. The cooling system 100 may comprise a first plate 102 comprising a first surface 104, a first width 106 and a first thickness 108. The cooling system 100 may further comprise a second plate 110 comprising a second surface 112, a second width 114 and a second thickness 116. The first plate 102 and the second plate 110 can be coupled at the first surface 104 and the second surface 112 by brazing the plates together, by welding the plates together, or the like, to create a seal between the first plate 102 and the second plate 110. The first plate 102 and/or the second plate 110 can be formed of metal, such as, for example, aluminum or a metal comprising aluminum.

In accordance with examples of the disclosure, the first width 106 is greater than the second width 114. The second thickness 116 can be greater than the first thickness 108. The first thickness 108 can be 1 centimeter to 10 centimeters, 2 centimeters to 8 centimeters, or 4 centimeters to 6 centimeters. The second thickness 116 can be 2 centimeters to 15 centimeters, 4 centimeters to 12 centimeters, or 6 centimeters to 10 centimeters. The first width 106 can be 140 millimeters to 420 millimeters. The second width 114 can be 25 millimeters to 290 millimeters.

Further referencing FIGS. 1A and 1B, the cooling system 100 can comprise a cooling fluid assembly 122. The cooling fluid assembly 122 may comprise a cooling fluid inlet 118 and a cooling fluid outlet 120. The cooling fluid assembly 122 is configured to connect the cooling system 100 to a cooling fluid source (not shown), such that the cooling fluid inlet 118 can receive coolant from the cooling fluid source. The cooling fluid outlet 120 can recycle the coolant to the cooling fluid source. The coolant can comprise chilled water, chilled deionized water or any other suitable coolant.

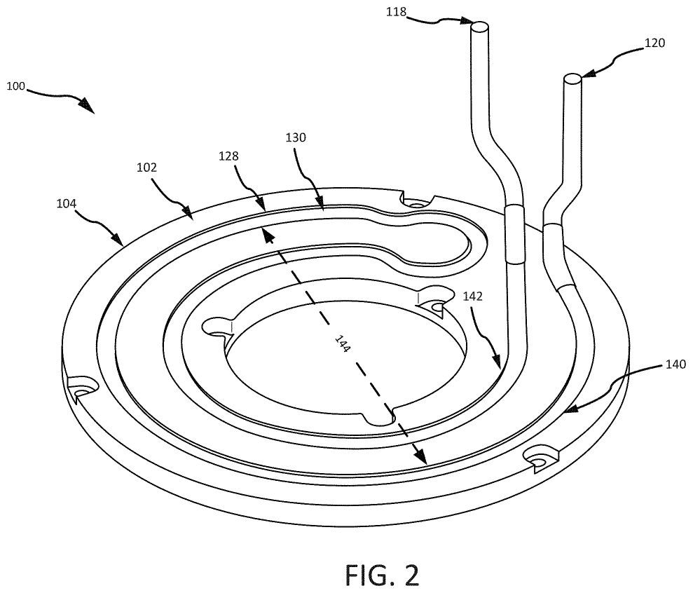

With reference to FIG. 2, the first plate 102 can comprise a groove 128, which extends into the first plate 102 from the first surface 104. When the first surface 104 and the second surface 112 are coupled together, they can form a conduit comprising the groove 128 enclosed by a portion of the second surface 112. A metal tube 130 can be disposed within the conduit. The metal tube 130 can comprise or be formed of stainless steel, aluminum, aluminum alloy, passivated nickel, Hastelloy, or the like. The cooling fluid inlet 118 can be at a first end of the metal tube 130 and the cooling fluid outlet 120 can be at a second end of the metal tube 130.

With continued reference to FIGS. 1A, 1B and 2, each of the first plate 102 and the second plate 110 can form an annular structure (e.g., an annular ring shape). The second plate 110 can comprise an inner diameter 124 and an outer diameter 126. The groove 128 can be continuous and comprise a plurality of concentric arcuate shaped sections. The plurality of concentric arcuate shaped sections can comprise a first arcuate shaped section 140 and a second arcuate shaped section 142. As illustrated in FIG. 2, the plurality of concentric arcuate shaped sections 140, 142 can form a serpentine structure in the first plate 102. The groove 128 can comprise an arcuate shape comprising a groove diameter 144 that is greater than the inner diameter 124 but less than the outer diameter 126. In accordance with other examples, the conduit can be used directly as a cooling channel for the cooling fluid without having the metal tube 130 in the conduit.

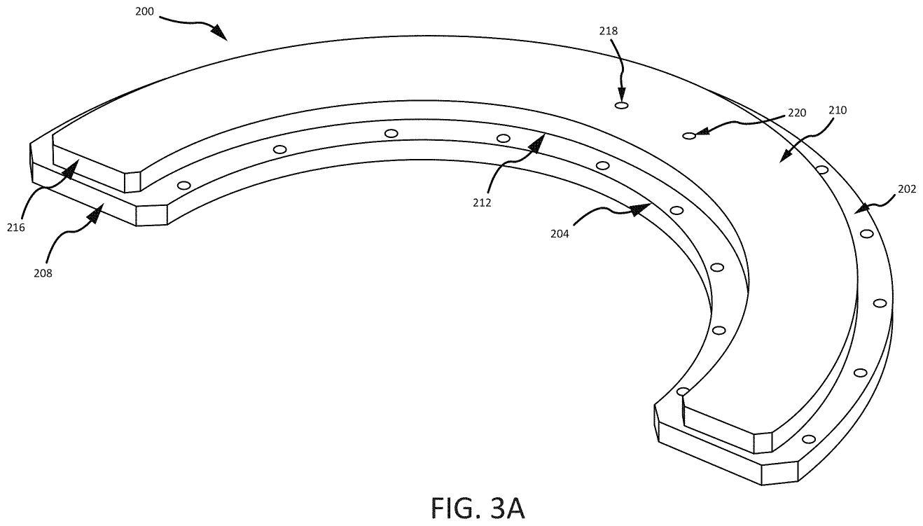

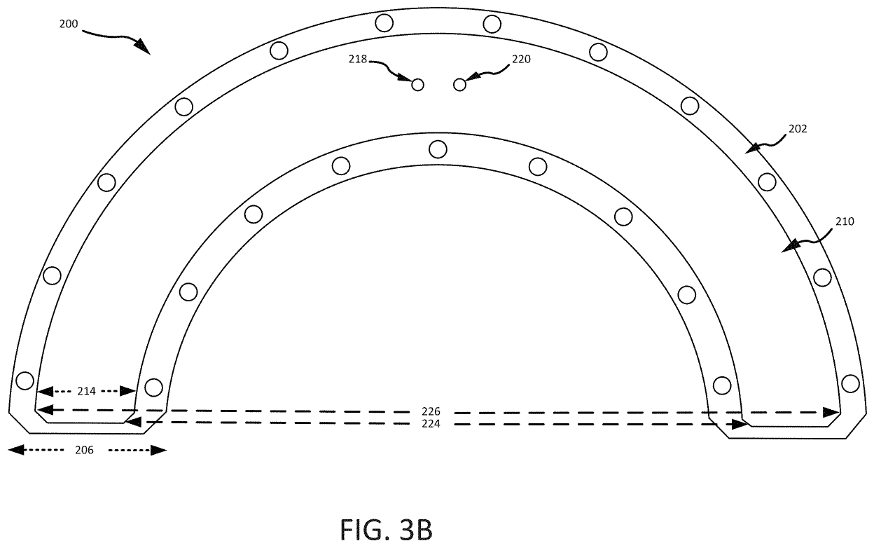

FIGS. 3A and 3B illustrate an exemplary cooling system 200 in accordance with additional examples of the disclosure. The cooling system 200 includes a first plate 202 comprising a first surface 204, a first width 206 and a first thickness 208. The cooling system 200 can also include a second plate 210 comprising a second surface 212, a second width 214 and a second thickness 216. The first plate 202 and the second plate 210 can be coupled at the first surface 204 and the second surface 212 by brazing the plates together, by welding the plates together, or another suitable method of coupling that creates a seal between the first plate 202 and the second plate 210. The first plate 202 and the second plate 210 can be formed of metal, such aluminum or a metal comprising aluminum. The first width 206 can be greater than the second width 214. The second thickness 216 can be greater than the first thickness 208. The first thickness 208 can be 1 centimeter to 10 centimeters, 2 centimeters to 8 centimeters, or 4 centimeters to 6 centimeters. The second thickness 216 can be 2 centimeters to 15 centimeters, 4 centimeters to 12 centimeters, or 6 centimeters to 10 centimeters.

The cooling system 200 can comprise a cooling fluid assembly, which comprises a cooling fluid inlet 218 and a cooling fluid outlet 220. The cooling fluid assembly can connect to a cooling fluid source (not shown) such that the cooling fluid inlet 218 can receive coolant from the cooling fluid source and the cooling fluid outlet 220 can recycle coolant to the cooling fluid source. The coolant can be a coolant as described above.

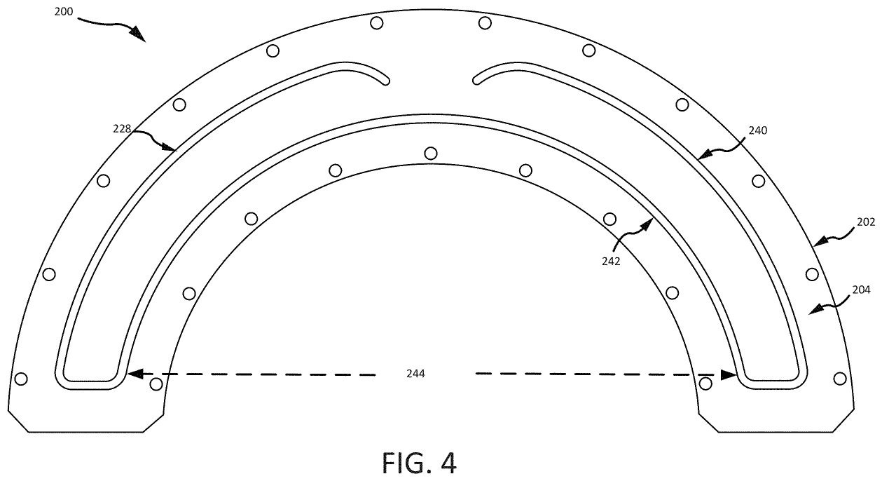

With reference to FIG. 4, the first plate 202 can comprise a groove 228, which extends from within the first plate 202 to the first surface 204. When the first surface 204 and the second surface 212 are coupled together, first surface 204 and second surface 212 can form a conduit comprising the groove 228 enclosed by a portion of the second surface 212. A metal tube can be disposed within the conduit. The metal tube can be formed of stainless steel, aluminum, aluminum alloy, passivated nickel, Hastelloy, or the like. The cooling fluid inlet 218 can be at a first end of the metal tube and the cooling fluid outlet 220 can be at a second end of the metal tube.

With reference to FIGS. 3A, 3B and 4, the first plate 202 and the second plate 210 can form a partial annular structure. The second plate 210 can comprise an inner diameter 224 and an outer diameter 226. The groove 228 can be continuous and comprise a plurality of concentric arcuate shaped sections. The plurality of concentric arcuate shaped sections can comprise a first arcuate shaped section 240 and a second arcuate shaped section 242. As illustrated in FIG. 4, the plurality of concentric arcuate shaped sections 240, 242 can form a serpentine structure in the first plate 202. The groove 228 can comprise an arcuate shape comprising a groove diameter 244 that is greater than the inner diameter 224 but less than the outer diameter 226. In accordance with examples of the disclosure, the conduit can be used directly as a cooling channel for the cooling fluid without having the metal tube in the conduit.

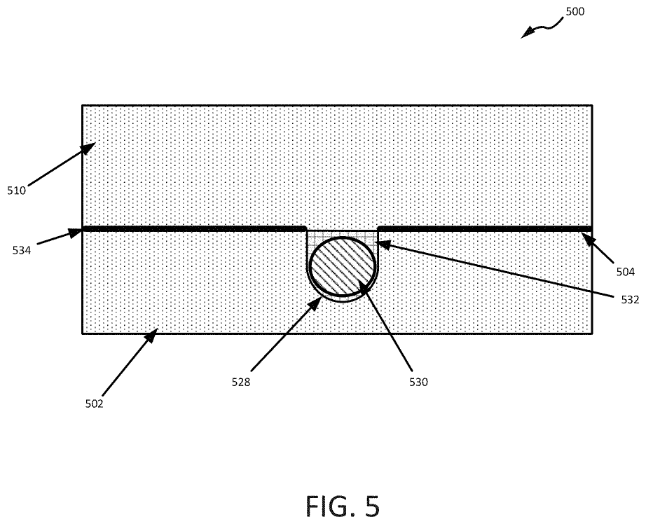

FIG. 5 illustrates a cross-sectional view of a cooling system 500, which can be the same or similar to cooling systems 100 or 200. FIG. 5 illustrates a first plate 502 coupled to and a second plate 510 by brazing or welding. The first plate 502 and the second plate 510 can be formed of metal, such as aluminum, stainless steel, aluminum alloy, passivated nickel, Hastelloy, or the like. The first plate 502 and second plate 510 can be formed of the same material or different materials. The first plate 502 can be the same or similar to first plate 102 or 202. The second plate 510 can be the same or similar to the second plate 110 or 210. The first plate 502 and the second plate 510 can be coupled together by using fill layer 534 to braze or weld the plates together. The fill layer 534 can be a brazing material or a welding material to couple the first plate 502 and the second plate 510. The brazing material can be or comprise nickel, zinc, steel or any other suitable metal for brazing the (e.g., aluminum) plates together. The welding material can be aluminum or comprise tungsten, or any other suitable metal commonly used for welding together aluminum.

The first plate 502 can have a groove 528 which extends from inside the first plate 502 to the top surface 504 of the first plate 502. The groove 528 can be as described above in connection with grooves 128 and 228. The groove 528 can be covered or sealed by the second plate 510 to form a conduit 532. The conduit 532 can be used as a coolant channel to deliver or circulate cooling fluid through the cooling system. In some cases, a metal tube 530 can be disposed within the conduit 532 to deliver the cooling fluid to the cooling system. The metal tube 530 can be as described above in connection with FIGS. 1A-4. The coolant can be received at a cooling fluid inlet of the metal tube 530 and exit through a cooling fluid outlet of the metal tube 530, as described above.

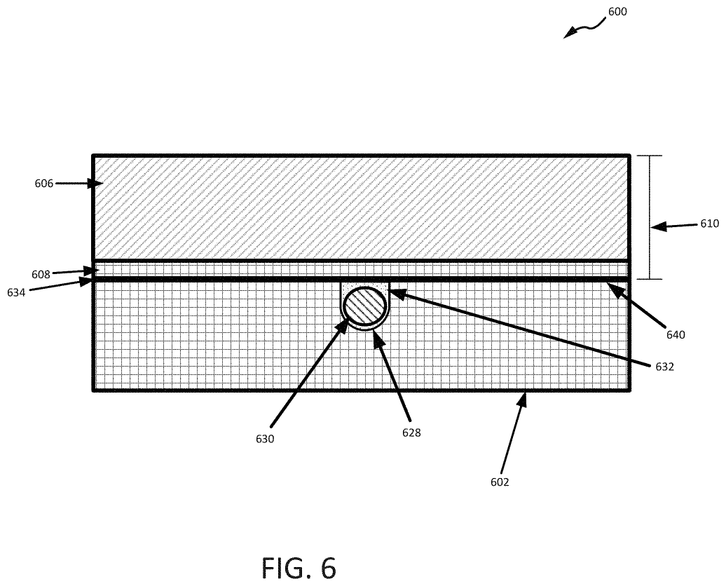

FIG. 6 illustrates a cutaway view of an additional embodiment of a cooling system 600, which can be configured as cooling system 100 or 200, described above. The cooling system 600 may comprise a first plate 602 and a second plate 610 that can be coupled together by brazing or welding at a first surface 640 of the first plate 602 and a surface of the second plate 610. The first plate 602 can be the same or similar to first plate 102 or 202. The second plate 610 can be the same or similar to second plate 110 or 210. The first plate 602 comprises a first surface, a first thickness, a first width, and a groove 628.

The second plate 610 is a bi-metal plate comprising a second layer 606 and a first layer 608, wherein the second plate 610 comprises a second thickness and second width (similar to second plates 110 and 210). The second layer 606 and the first layer 608 can be coupled together by brazing or welding. The first layer 608 can comprise or be formed of stainless steel. The second layer 606 can comprise or be formed of a second metal such as aluminum, stainless steel, aluminum alloy, passivated nickel, Hastelloy, or the like.

The first plate 602 can be formed of a metal, such as, for example, stainless steel. The first plate 602 and the first layer 608 can be formed of the same material or different materials. The first plate 602 and the second plate 610 can be coupled together by using a fill layer 634 to braze or weld the plates together. The weld can be directly in contact with the first layer 608 of the second plate 610 and the first surface 640 of the first plate 602. The fill layer 634 can be a brazing material or a welding material to couple the first plate 602 and the second plate 610. The brazing material can be nickel, zinc, steel or any other suitable metal. The welding material can be tungsten, or any other suitable metal.

The first plate 602 may comprise the groove 628, which extends into the first plate 602 from the first surface 640 of the first plate 602. The groove 628 can be the same shape as grooves 128 and/or 228, described above. The groove 628 can be covered or sealed by the second plate 610 using one or more of a weld and a brazing material at the first surface 640 and the first layer 608 to form a conduit 632 comprising the groove 628 enclosed by a portion of the first layer 608. A cooling fluid inlet, such as cooling fluid inlets 118 and 218, and a cooling fluid outlet, such as cooling fluid outlets 120 and 220, can be fluidly connected to the conduit 632. The conduit 632 can be used as a coolant channel to deliver cooling fluid to the cooling system through a cooling fluid inlet and through a cooling fluid outlet, as described above. In some cases, a metal tube 630 can be disposed within the conduit 632 to deliver the cooling fluid to the cooling system. The metal tube 630 can be formed of stainless steel, aluminum, aluminum alloy, passivated nickel, Hastelloy, or the like. The cooling systems described herein can be utilized in conjunction with a gas phase reactor system for a multitude of processes, including but not limited to, ALD, CVD, metalorganic chemical vapor deposition (MOCVD), molecular beam epitaxy (MBE), physical vapor deposition (PVD), plasma-enhanced chemical vapor deposition (PECVD), cleaning, and etching.

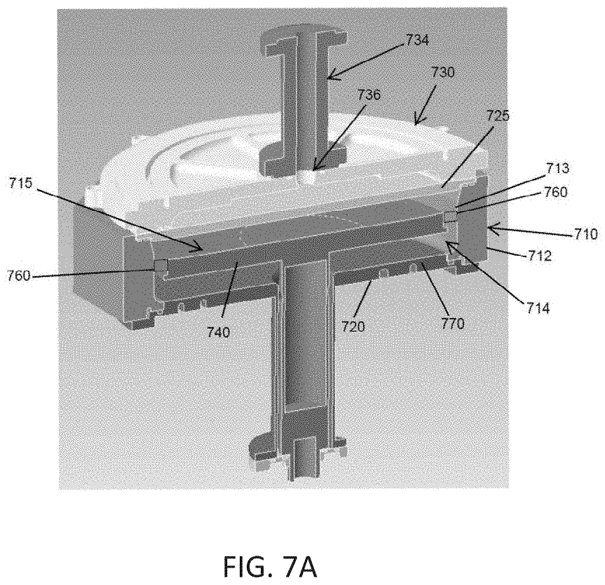

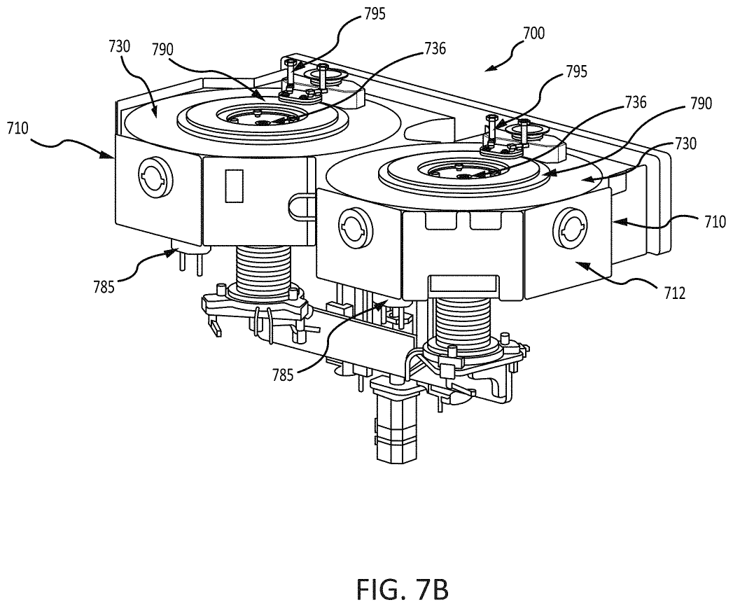

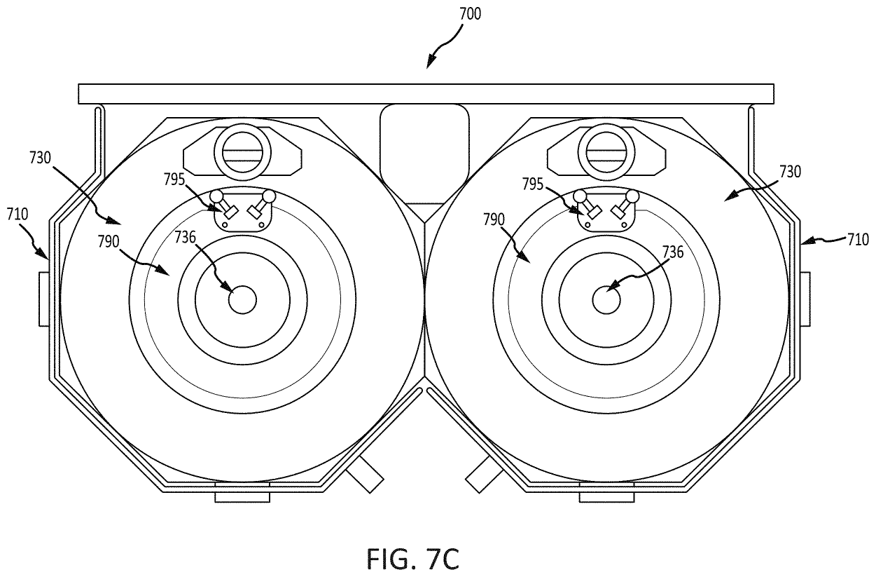

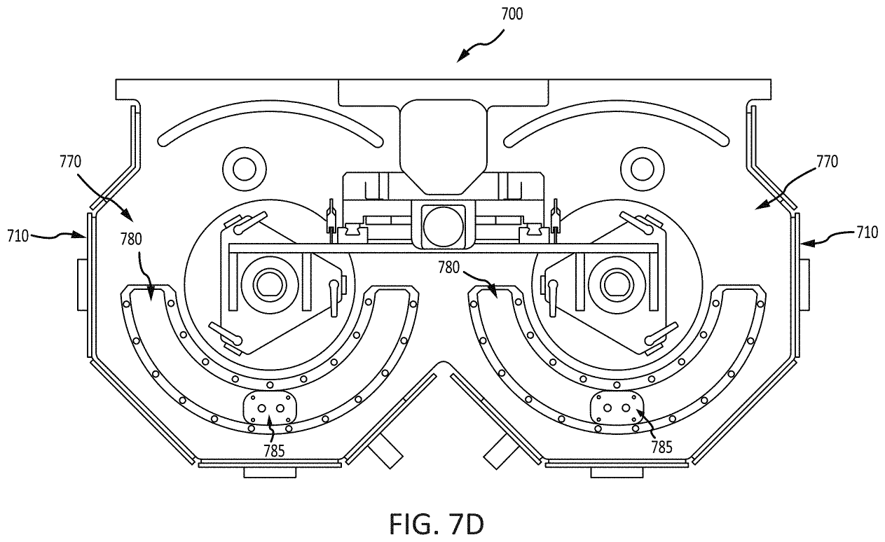

FIGS. 7A-7D illustrate a gas phase reactor system (sometimes referred to herein simply as system) 700 in accordance with exemplary embodiments of the disclosure. In this regard, FIG. 7A is a perspective cross-sectional view of a portion of one reaction chamber 710 of the exemplary gas phase reactor system 700. The gas phase reactor system 700 can be configured for use in a variety of reactor system designs. FIGS. 7B, 7C, and 7D illustrate modules including two reaction chambers 710 and at least one cooling system (790 and 780). The gas phase reactor system 700 includes one or more reaction chambers 710, with a body 712 defining a sidewall 713 and can include a plate 770 defining a bottom of reaction chamber 710. The reaction chamber 710 includes a lower region 714 and an upper region 715. The upper region 715 is provided with a gas distribution device, such as a showerhead 725, disposed above a susceptor 740 and enclosed by a showerhead lid 730 of the gas phase reactor system 700. The gas phase reactor system 700 can further include a showerhead lid opening 736 and a showerhead inlet 734 for providing process gases through the showerhead 725 into the upper region 715.

The gas phase reactor system 700 also includes an interface plate assembly 760 that is adapted to mate with the susceptor 740 to define lower region 714 and upper region 715. The body 712 of the reaction chamber 710 has a bottom surface 720.

To control temperatures of the plate 770 and/or the lower region 714, it is desirable to provide a cooling system. With this in mind, a first cooling system 780 can be coupled to the bottom surface 720 of plate 770. The first cooling system can be either cooling system 500 or 600 as described previously. As shown in FIG. 7D, the first cooling system 780 can be a partial annular structure, such as cooling system 200.

It is also desirable to control temperatures of the showerhead 725 and the showerhead lid 730. With this in mind, a second cooling system 790 can be coupled to the upper surface of the showerhead lid 730 of the reaction chamber 710. The second cooling system 790 is not shown in FIG. 7A but is shown in FIGS. 7B and 7C. The second cooling system 790 can be cooling system 500 or 600 described previously. As shown in FIG. 7C, the second cooling system 790 can form an annular structure, such as cooling system 100. The cooling systems 780 and 790 can also include a coupling assembly 785 and 795, respectively. The coupling assemblies 785 and 795 can include a cooling fluid inlet and a cooling fluid outlet from each cooling system to a cooling fluid source, as described above in connection with cooling systems 100 and 200.

The gas phase reactor system 700 may be configured for a relatively high upper temperature limit, such as 450° C. The components of the gas phase reactor system 700 may be fabricated of a variety of materials for use in such a higher temperature application. For example, but not as a limitation, the susceptor 740 may be formed of C22, the interface plate assembly 760 may be formed of stainless steel (e.g., 316 SS or the like), and the reaction chamber 710 may be formed of aluminum (e.g., 6061 Al or the like).

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, can become apparent to those skilled in the art from the description. Such modifications and embodiments are also intended to fall within the scope of the appended claims.

What is claimed is:

1. A cooling system for a gas phase reactor, the cooling system comprising:
a first plate comprising a first surface, a first width and a first thickness;
a second plate comprising a second surface, a second width and a second thickness,
wherein a groove is formed within the first plate and extends to the first surface of the first plate, and
wherein the first plate and the second plate are coupled together at the first surface and the second surface to form a conduit comprising the groove enclosed by a portion of the second surface; and
a metal tube, wherein the metal tube is disposed within the conduit; and wherein the metal tube comprises a cooling fluid inlet at a first end of the metal tube and a cooling fluid outlet at a second end of the metal tube.

2. The cooling system of claim 1, wherein the first plate and the second plate are formed of aluminum.

3. The cooling system of claim 1, wherein the first width is greater than the second width.

4. The cooling system of claim 1, wherein the second thickness is greater than the first thickness.

5. The cooling system of claim 1, wherein the first plate and the second plate are brazed together at the first surface and the second surface.

6. The cooling system of claim 1, wherein the metal tube is formed of stainless steel.

7. The cooling system of claim 1, wherein the first plate and the second plate each form a partial annular structure, the second plate comprising an inner diameter and an outer diameter, and
wherein the groove comprises an arcuate shape comprising a groove diameter that is greater than the inner diameter and less than the outer diameter.

8. The cooling system of claim 1, wherein the first plate and the second plate each form an annular structure, the second plate comprising the inner diameter and the outer diameter, and
wherein the groove is continuous and comprises a plurality of concentric arcuate shaped sections.

9. A cooling system for a gas phase reactor, the cooling system comprising:
a first plate comprising a first surface, a first thickness, a first width, and a groove is formed within the first plate, wherein the groove extends to the first surface of the first plate;
a second plate comprising a first layer and a second layer, wherein the second plate comprises a second thickness and a second width,
wherein the first plate and the second plate are coupled using one or more of a weld and a brazing material at the first surface and the first layer to form a conduit comprising the groove enclosed by a portion of the first layer; and
a cooling fluid inlet and a cooling fluid outlet, and wherein the cooling fluid inlet and the cooling fluid outlet are fluidly connected to the conduit.

10. The cooling system of claim 9, wherein the second layer is formed of a second metal.

11. The cooling system of claim 9, wherein the first layer is formed of stainless steel.

12. The cooling system of claim 9, wherein the first plate is formed of stainless steel.

13. The cooling system of claim 12, comprising the weld directly in contact with the first layer of the second plate and the first surface of the first plate.

14. The cooling system of claim 9, further comprising a metal tube, wherein the metal tube is disposed within the conduit.

15. The cooling system of claim 9, wherein the first width is greater than the second width, and wherein the second thickness is greater than the first thickness.

16. The cooling system of claim 9, wherein the first plate and the second plate each form a partial annular structure, and
wherein the groove comprises a serpentine path between the cooling fluid inlet and the cooling fluid outlet.

17. The cooling system of claim 9, wherein the first plate and the second plate each form an annular structure, and
wherein the groove comprises a continuous serpentine path between the cooling fluid inlet and the cooling fluid outlet.

18. A gas phase reactor system, comprising:
a reaction chamber comprising an upper region and a lower region;
a showerhead disposed within the upper region; and
a first cooling system disposed below the lower region, and comprising:
a first plate comprising a first surface;
a second plate comprising a second surface,
wherein a first groove is formed within the first plate and extends to the first surface of the first plate, and
wherein the first plate and the second plate are coupled together at the first surface and the second surface to form a first conduit comprising the first groove enclosed by a portion of the second surface; and
a first metal tube, wherein the metal tube is disposed within the conduit; and wherein the first metal tube comprises a first cooling fluid inlet at a first end of the first metal tube and a first cooling fluid outlet at a second end of the first metal tube; and
a second cooling system disposed above the showerhead, and comprising:
a third plate comprising a third surface;
a fourth plate comprising a fourth surface,
wherein a second groove is formed within the third plate and extends to the third surface of the third plate, and
wherein the third plate and the fourth plate are coupled together at the third surface and the fourth surface to form a second conduit comprising the second groove enclosed by a portion of the fourth surface; and
a second metal tube disposed within the conduit, and wherein the second metal tube comprises a second cooling fluid inlet at a first end of the second metal tube and a second cooling fluid outlet at a second end of the second metal tube.

19. The gas phase reactor system of claim 18, wherein the cooling system further comprises a coupling assembly for connecting the cooling fluid inlet and the cooling fluid outlet to a cooling fluid source.

20. The gas phase reactor system of claim 18, wherein the first plate and the second plate each form a partial annular structure and the third and fourth plate each have an annular ring shape.
